(19) United States
(12) Patent Application Publication
(10) Pub. No.: US 2024/0162105 A1
(43) Pub. Date: May 16, 2024

(54) Semiconductor Device with Electric Field Management Structures

(71) Applicant: Massachusetts Institute of Technology, Cambridge, MA (US)

(72) Inventors: Tomas Palacios, Belmont, MA (US); Ahmad Zubair, Hillsboro, OR (US); John Niroula, Los Angeles, CA (US)

(73) Assignee: Massachusetts Institute of Technology, Cambridge, MA (US)

(21) Appl. No.: 18/548,704

(22) PCT Filed: Mar. 29, 2022
(86) PCT No.: PCT/US2022/022285

§ 371 Date: Sep. 1, 2023

Related U.S. Application Data
(60) Provisional application No. 63/168,645, filed on Mar. 31, 2021.

(51) Int. Cl. H01L 23/31; H01L 29/20; H01L 29/778; H01L 29/78; H01L 29/861; H01L 29/872

(52) U.S. Cl. CPC H01L 23/3192; H01L 23/3171; H01L 29/2003; H01L 29/7786; H01L 29/7813; H01L 29/7827; H01L 29/8613; H01L 29/872; H01L 29/8725

(57) ABSTRACT

A semiconductor device having an electric field management layer. The electric field management layer comprises a material with a relatively high dielectric constant that minimizes the risk of an electric field within the semiconductor device breaking down and damaging the semiconductor device.

### RELATED APPLICATIONS

This application claims priority to and benefit of U.S. Provisional Patent Application No. 63/168,645 (filed Mar. 31, 2021), which is incorporated here by reference in its entirety.

### FIELD

This disclosure relates to semiconductor devices and, more particularly, to structures for managing electric fields in semiconductor devices.

### BACKGROUND

Electronic semiconductor devices and circuits often operate in the presence of an electric field. For example, operation of high voltage circuits, such as high voltage switches and other high-frequency power electronics, sometimes require large electric fields across the semiconductor device. If the strength of the electric field in any of the regions of the semiconductor device exceeds the critical electric field in the material of that region, the device can break down (e.g. a portion of an insulator in the semiconductor device becomes electrically conductive), allowing the electric field to drive current through the device and cause damage to the semiconductor device. To prevent this, electric field management structures can be built into the device.

In the off-state of an ideal power semiconductor device, the maximum voltage handling capability is determined by the doping density and the thickness of the drift region of the semiconductor device. A breakdown may occur when the electric field in the drift region exceeds the threshold for the onset of impact ionization followed by carrier multiplication. In practical power devices, electric field crowding (i.e. a non-homogenous distribution of an electric field) can occur near an edge structure resultant from fabricating a semiconductor device. Such electric field crowding can cause the electric field to exceed the critical value leading to premature breakdown of semiconductor devices. To avoid such a breakdown, field management structures may be used to redistribute the electric field near such edges to reduce (and ideally minimize) the peak electric field and thereby prevent premature breakdown from occurring in the semiconductor device.

### SUMMARY

In accordance with the concepts structures and techniques disclosed herein, described is an electric field management structure that may mitigate the electric field so that it does not cause breakdown in an underlying semiconductor.

In embodiments, the electric field management structure comprises a dielectric electric field management layer disposed over another layer (e.g. a dielectric passivation layer). The dielectric electric field management layer is provided from a material having a dielectric constant (κ) higher than the other layer (e.g. the dielectric passivation layer). The ratio of dielectric constants determines the reduction of electric field. Since the ratio of dielectric constants (κ₅₀₄/κ₅₀₆)determines the reduction of electric field, in embodiments, the use of a material having a relatively high dielectric constant for the dielectric electric field management layer is desirable.

In embodiments, structures or devices may benefit from having more than one field management structure, and one or more of the field management structures could disposed in, on, or around regions where a peak electric field is not the highest in the device or structure. Thus, in embodiments, multiple field management structures provided in accordance with the concepts, structure, and techniques described herein may be used for multiple electric field regions.

In embodiments, a semiconductor device may comprise a dielectric layer of graded composition and one or more field management structures disposed to mitigate one or more high field regions in the device.

One general aspect includes a semiconductor device with electric field management. The semiconductor device also includes a substrate. The device also includes a dielectric passivation layer disposed on a drift region, with the dielectric passivation layer having a dielectric constant. The device also includes a gate terminal disposed on the dielectric passivation layer. The device also includes an electric field management layer having a dielectric constant which is higher than the dielectric constant of the dielectric passivation layer, with the electric field management layer disposed over the dielectric passivation layer.

Implementations may include one or more of the following features. The semiconductor device the electric field management layer is disposed over the dielectric passivation layer so as to form a junction with the dielectric passivation layer at a location substantially proximate to a peak electric field within the semiconductor device. The junction is formed at a three-way junction of the dielectric passivation layer, the electric field management layer, and the gate terminal.

One general aspect includes a semiconductor device. The semiconductor device also includes an electric field management layer formed from a first material. The device also includes where the electric field management layer is disposed over a first layer formed from a second, different material, with the first layer having a dielectric constant which is lower than the dielectric constant of the electric field management layer.

Implementations may include one or more of the following features. The semiconductor device where the first layer is provided as a dielectric passivation layer. The first material can be any of GaN, SiC, GaₓO_{y}, diamond, silicon, GaAs, AlₓGa₁₋ₓN, c-BN, h-BN, MX₂ (where M=Mo, W; X=S, Se, Te). The dielectric or semiconductor material may be grown and/or deposited using any of a plurality of different techniques. The electric field management layer is disposed adjacent to a gate terminal, where a dielectric passivation layer, electric field management layer, and gate terminal form a three-way junction.

One general aspect includes a semiconductor structure with a semiconductor region that includes at least one semiconductor material. The structure also includes two dielectric regions with arbitrary thickness, the two dielectric regions in contact with a wide bandgap semiconductor and with one of the dielectric regions having a relative permittivity which is higher than a relative permittivity of the other one of the dielectric regions. The relative permittivity of at least one dielectric region may be higher than the underlying semiconductor material.

Implementations may include one or more of the following features. The dielectric or semiconductor material may be grown using any of a plurality of techniques including, but not limited to metalorganic chemical vapor deposition or molecular-beam epitaxy. The dielectric or semiconductor material may be deposited using a plurality of techniques (e.g. atomic layer deposition, sputtering, chemical vapor deposition, spin-casting) or transferred.

The semiconductor device also includes a first layer. The device also includes a second layer disposed on the first layer and forming an interface between the first layer and the second layer. The device also includes an electric field management layer disposed on or near the interface, the electric field management layer having a relatively high relative permittivity to reduce a peak electric field forming at the interface.

Implementations may include one or more of the following features. The semiconductor device where the first layer may include a terminal of the semiconductor device. The semiconductor device may include a fourth layer disposed between the electric field management layer and the first layer, between the electric field management layer and the second layer, or both. The fourth layer may include a material that has a lower permittivity than the permittivity of the electric field management layer. The device is a transistor. The device is a diode. The electric field management layer has a dielectric constant between about 9 and about 300. The electric field management layer may include gaps. A portion of the electric field management layer forms a spacer between the first and second layers. The first and second layers may include terminals of the semiconductor device.

### BRIEF DESCRIPTION OF THE DRAWINGS

The foregoing features may be more fully understood from the following description of the drawings. The drawings aid in explaining and understanding the disclosed technology. Since it is often impractical or impossible to illustrate and describe every possible embodiment, the provided figures depict one or more exemplary embodiments. Accordingly, the figures are not intended to limit the scope of the invention. Like numbers in the figures denote like elements.

FIG. 1 is an isometric view of a semiconductor device of gallium nitride (GaN) vertical power fin field-effect-transistor (FinFET).

FIG. 2(a) is a cross sectional view of a semiconductor device.

FIGS. 2(b) and 2(c) are graphs representing an electric field within the semiconductor device of FIG. 2(a).

FIG. 3(a) is a cross sectional view of an electric field distribution within a semiconductor device.

FIGS. 3(b) and 3(c) are graphs representing an electric field within the semiconductor device of FIG. 3(a).

FIG. 4(a) is a cross sectional view of a semiconductor device.

FIG. 4(b) is a cross sectional view of a semiconductor device showing the location of a peak electric field.

FIG. 5(a) is a cross sectional view of a semiconductor device having a layer with a high dielectric constant κ.

FIG. 5(b) is a cross sectional view of a semiconductor device having a layer with a high dielectric constant κ and showing the location of a peak electric field.

FIG. 6 is a cross sectional view of a semiconductor device with a high-κ layer and a low-κ passivation layer.

FIGS. 7(a), 7(b), and 7(c) are cross sectional views of vertical diodes having electric field management layers.

FIGS. 8(a), 8(b), and 8(c) are also cross sectional images of vertical diodes having electric field management layers.

FIGS. 9(a) and 9(b) are cross sectional images of vertical transistors having electric field management layers.

FIGS. 10(a) and 10(b) are also cross sectional images of vertical transistors having electric field management layers.

FIGS. 11(a) and 11(b) are cross sectional images of quasi-vertical transistors having electric field management layers.

FIGS. 12(a), 12(b), and 12(c) are cross sectional images of lateral transistors having electric field management layers.

FIG. 13(a) is a cross sectional image of a HEMT transistor having a high-κ electric field management layer.

FIGS. 13(b), 13(c), and 13(d) are top view of the HEMT transistor of FIG. 13(a).

FIGS. 14(a), 14(b), and 14(c) are cross sectional images of vertical diodes having electric field management layers.

FIGS. 15(a), 15(b), and 15(c) are also cross sectional images of vertical diodes having electric field management layers.

FIGS. 16(a) and 16(b) are cross sectional images of vertical transistors having electric field management layers.

FIGS. 17(a) and 17(b) are cross sectional images of vertical transistors having electric field management layers.

FIGS. 18(a) and 18(b) are cross sectional images of quasi-vertical transistors having electric field management layers.

FIGS. 19(a), 19(b), and 19(c) are cross sectional images of lateral transistors having electric field management layers.

FIG. 20(a) is a cross sectional image of HEMT transistor having a high-κ electric field management layer.

FIGS. 20(b), 20(c), and 20(d) are top view of the HEMT transistor of FIG. 13(a).

### DETAILED DESCRIPTION

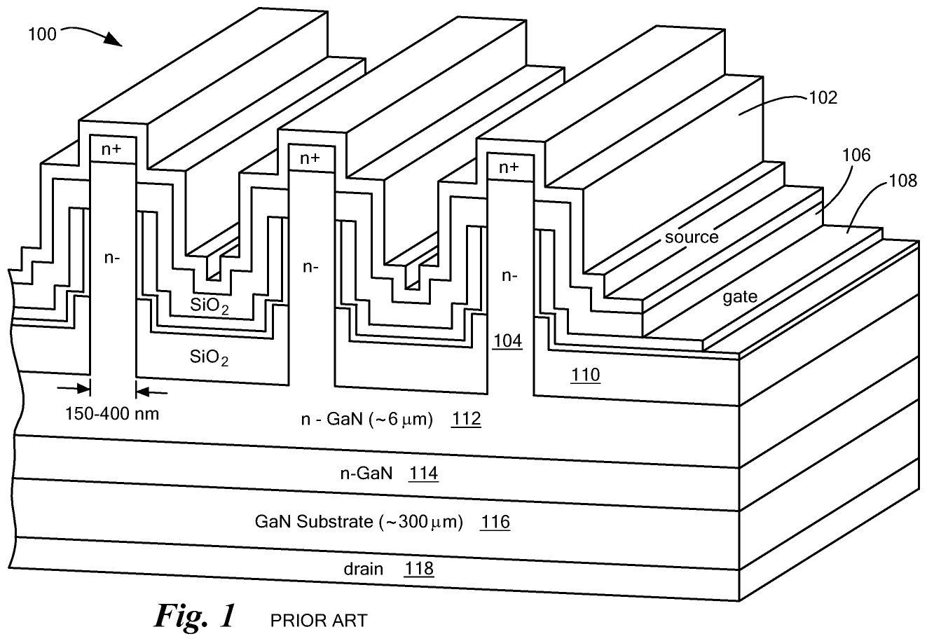

FIG. 1 is an isometric view of a prior art field-effect transistor (FET) 100 showing a source structure 102 wrapped around (e.g. over) n-doped vertical fin structures 104. Devices like FET 100 may be referred to as vertical fin field-effect-transistors (FinFETs) due to the fin-like vertical structures. The source structure is disposed on a silicon oxide separation layer 106 (e.g. an SiO₂ separation layer), which in turn is disposed over a split gate structure 108. Also shown is a SiO₂ layer 110 between the gate and an n-doped gallium nitride (GaN) layer 112 (n-GaN layer) that comprises the vertical fins. Another n-doped GaN layer 114 is disposed over the GaN substrate 116, which in turn is disposed over the drain layer 118.

The vertical power FinFET 100 can act, for example, as a high voltage switch for high-frequency power applications.

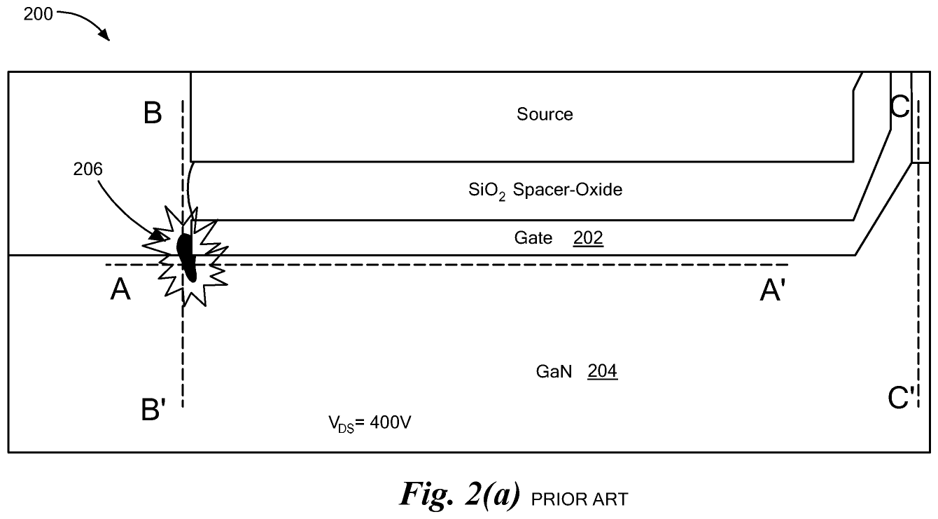

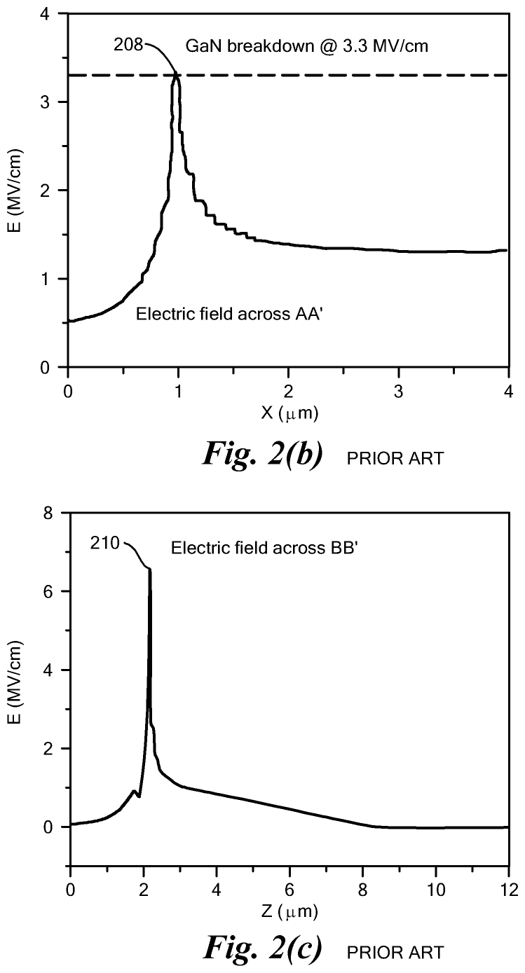

Referring to FIG. 2, a cross sectional view of a portion of a FinFET 200 of the prior art shows an electric field mapping of the device in an off-state. As shown, the electric field may have high peaks at the corner of the gate 202 and GaN substrate 204, i.e. at location 206. The graph in FIG. 2(b) illustrates the value of the electric field along line A-A′. As seen, the electric field meets or exceeds the breakdown field for the GaN substrate at peak 208, which corresponds to point 206 in FIG. 2(a). The graph in FIG. 2(c) shows the electric field profile along the vertical B-B′ line. Again, the electric field meets or exceeds the breakdown field for the GaN substrate at peak 210, which also corresponds to point 206 in FIG. 2(a).

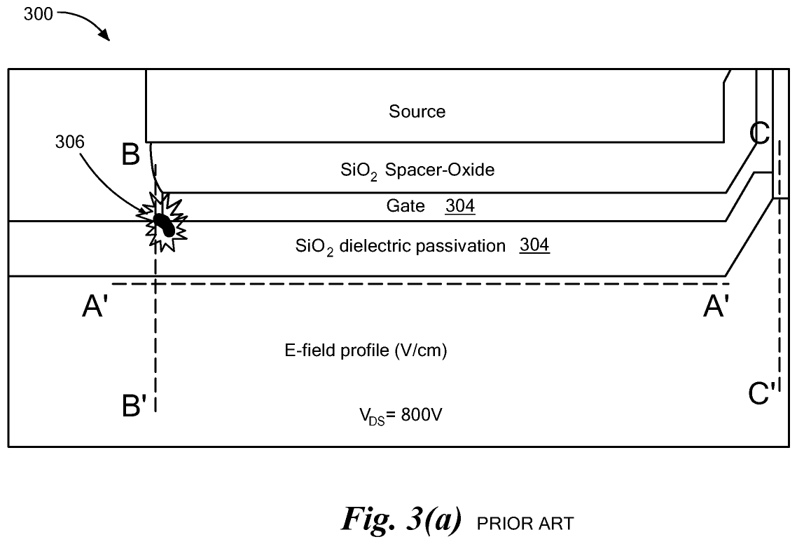

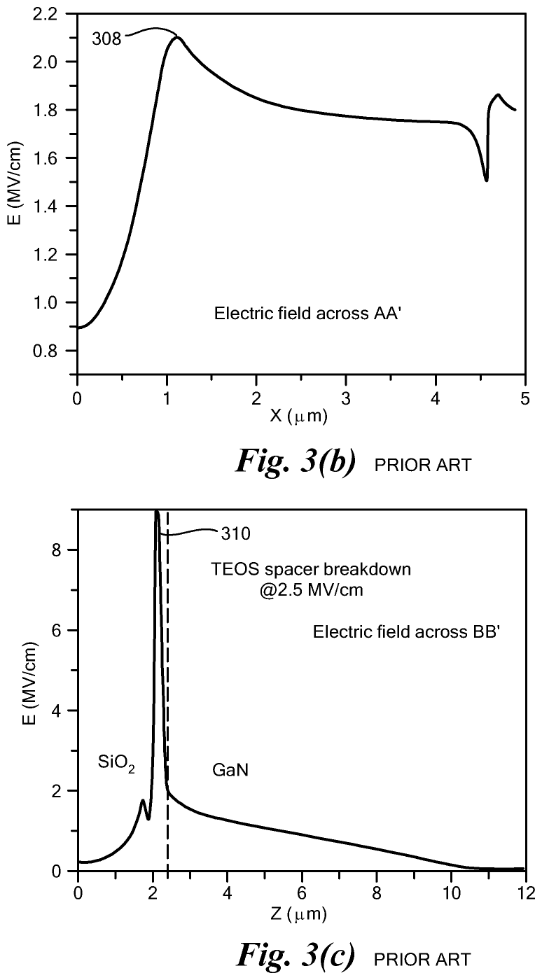

Referring to FIG. 3(a), a cross-sectional view of a FinFET 300 having a SiO₂ dielectric passivation layer 302 is shown. In this example, the electric field distribution within the device is shown at V_{DS}=800V and V_{GS}=0V in a GaN vertical power FinFET with ideal BV of 2100 V. Similar to FIG. 2, the peak electric field occurs at the corner of the gate 304 and the dielectric passivation layer 302, i.e. at point 306. The graph in FIG. 3(b) illustrates the value of the electric field along line A-A′. As seen, the electric field meets or exceeds the breakdown field for the substrate at peak 308, which corresponds to point 306. The graph in FIG. 3(c) shows the electric field profile along the vertical B-B′ line. Again, the electric field meets or exceeds the breakdown field for the GaN device at peak 310, which corresponds to point 306.

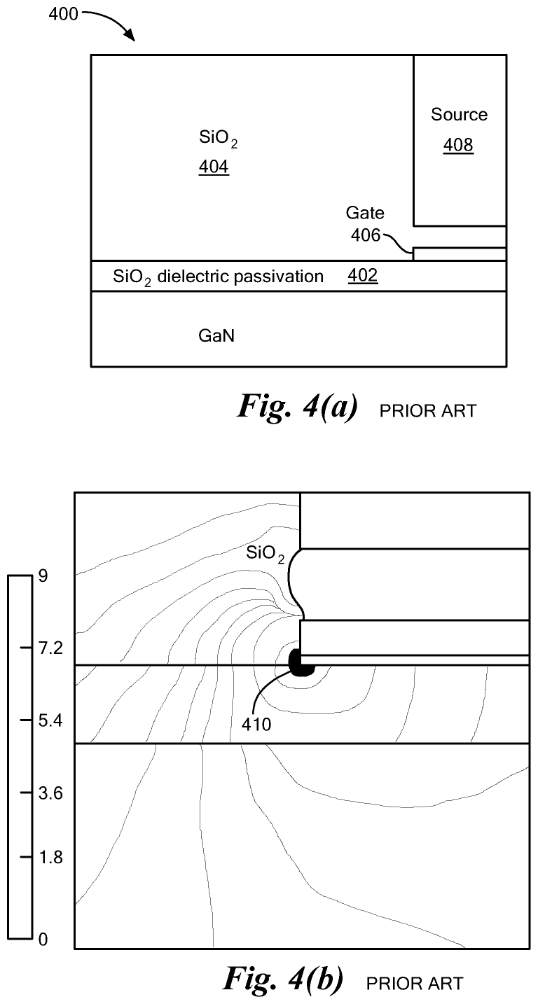

FIG. 4(a) is a cross-sectional view of a FinFET 400 of the prior art having a SiO₂ dielectric passivation layer 402 and a SiO₂ electric field management layer 404. The electric field management layer 404 is disposed on the dielectric passivation layer 402. In this example, the electric field management layer 404 extends between the gate 406 and source 408 terminals to act as a dielectric spacer between the source and gate.

FIG. 4(b) is a cross-sectional view of the FinFET 400, showing the electric field when the device is in the off state. The peak electric field occurs at point 410 at the corner of the gate 406 and the electric field management layer 404.

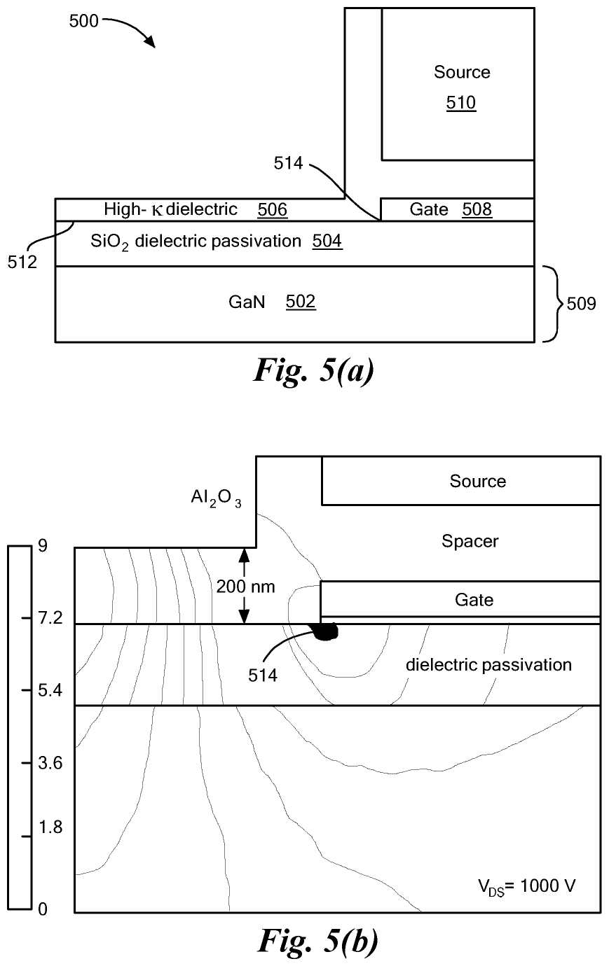

FIG. 5(a) shows a FinFET 500 with an electric field management layer 506 that may mitigate the electric field so that it does not cause breakdown in the underlying semiconductor. The operation of the electric field management layer can be explained using the normal boundary condition for the electric field at the interface of 504 and 506

$$( \frac{{E}_{506}}{{E}_{504}} = \frac{{κ}_{504}}{{κ}_{506}} ) ,$$

where E represents the electric field and κ represents the dielectric constant of the material.

In embodiments, the electric field management layer may be formed from binary oxides (e.g., AlOₓ, HfOₓ, ZrOₓ, LaXO_{y}, TiOₓ), doped oxides (HfₓM₁₋ₓO₂; M=Si, Zr, Al, La) semiconductors (e.g., AlN, Sc_{X}Al₁₋ₓN, Sc_{X}Ga₁₋ₓN, ScₓB₁₋ₓN), ferroelectrics (e.g., HZO, PZT, PVDF-TrFE), complex oxides (e.g., BaTiO₃, SrTiO₃), or layered materials (e.g., GaSe, SnTe, CuInP₂S₆) or their heterostructures with or without twisting in between layers (e.g., twisted bi-layer h-BN), or a graded composition of any of the materials above.

The semiconductor material (for example, a substrate) on which the electric field management layer 506 is disposed may comprise any of GaN, SiC, GaxO_{y}, diamond, silicon, GaAs, AlₓGa₁₋ₓN, c-BN, h-BN, MX₂ (where M=Mo, W; X=S, Se, Te).

The peak electric field may be scaled by the ratio of dielectric constants. For example, the use of Al₂O₃ (having a dielectric constant κ=8) instead of SiO₂ (having a dielectric constant of κ=3.9) will reduce the peak electric field strength by approximately 50% (i.e. the ratio of 3.9/8=0.4875). It should be appreciated that the configuration of the high-κ dielectric edge termination structure may also depend upon the geometry of the particular device. FinFET 500 includes an n-GaN drift region 502 and a dielectric passivation layer 504. In this example embodiment the n-GaN drift region has a height 509 of about 6 μm. Disposed on the dielectric passivation layer 504 is a dielectric electric field management layer 506 having a high dielectric constant (κ). In embodiments, the dielectric constant of the electric field management layer 506 is higher than the dielectric constant of the dielectric passivation layer 504. Since the ratio of dielectric constants (κ₅₀₄/κ₅₀₆) determines the reduction of electric field, the use of a dielectric with highest possible dielectric constant may be desirable. However, the peak electric field inside the electric field management layer 506 should not exceed the critical electric field of the material. The trade-off between dielectric constant and critical electric field of the dielectric materials should be considered while designing the edge termination structure. This results in a reduced peak electric field within the FinFET 500.

In the example embodiment of FIG. 5(a), the electric field management layer is disposed between the gate 508 terminal and the source terminal 510 of the FET. Thus, in this example embodiment, the electric field management layer may also act as a dielectric spacing layer between the source terminal 510 and gate terminal 508. It should be noted, however, that this is not required. That is, in other embodiments, a different dielectric layer may be disposed between the gate terminal 508 and the source terminal 510 as a spacer layer. One purpose of the spacer layer is to provide electrical isolation between gate and source terminals, but it also contributes to the gate to source capacitance of the device. It may be desirable to use a spacer layer with a relatively low dielectric constant (e.g., a dielectric material comprising SiO₂, B CB etc.) to maximize the frequency performance of the device.

In the example embodiment of FIG. 5(a), the electric field management layer 506 forms a junction with the dielectric passivation layer 504 along interface 512. Also, the field management layer 506, dielectric passivation layer 504, and gate terminal 508 form a junction at point 514. As noted above (and as may be most clearly seen in FIG. 5(b)), the peak electric field within FinFET devices tends to occur at or substantially about point 514. The structure (i.e. the junction between field management layer 506, dielectric passivation layer 504, and/or the gate terminal 508) mitigates electric field strength that exists across the device. In embodiments, this is due to the structure dissipating, or spreading out, the displacement field (i.e. the electric field multiplied by dielectric constant) inside 506 near the point 514 so that the peak electric field is lowered by the ratio of dielectric constants (κ₅₀₄/κ₅₀₆) and does not exceed the breakdown threshold of the device.

In power semiconductor devices, electric field crowding tends to occur substantially near the edge of the devices, and/or near the edge of layers or structures within the devices, which leads to premature breakdown. The edge termination structure (e.g. region 506) forms a junction at the edge of the device and helps to mitigate the electric field crowding. In embodiments, the field management structure comprises an encapsulation of dielectric material around the gate edge (i.e. at point 514). It should be appreciated that the high-κ dielectric edge termination structure need not wrap around the gate metal but should cover the interface between gate metal 508 and gate dielectric 512. In embodiments, wrapping the edge termination structure around the gate metal may be preferred. The effectiveness of the edge termination structure is reduced (and may not be sufficiently effective for some applications) if a gap exists between gate metal and dielectric structures.

The dielectric constant of the encapsulating materials (i.e. of electric field management layer 506) may be higher than that of underlying dielectric passivation layer 504. In some embodiments, the dielectric constant of the encapsulating materials may be at least two times greater than that of underlying dielectric passivation layer. Table 1 lists some dielectric materials that may be used to form the field management structure 506. These are some examples of commonly used high-κ materials that can used with SiO₂ as well as other field oxides such as Si₃N₄ and BCB etc.

TABLE 1
Different dielectric materials and relevant parameters

| Dielectric material | Dielectric constant | Critical Electric field (MV/cm) |
|---|---|---|
| Al₂O₃ | 9 | 8 |
| HfO₂ | 18-22 | 5 |
| ZrO₂ | 25 | 3-5 |
| La₂O₃ | 27 | 13.5 [1] |
| HfₓM₁₋ₓO₂ (M = Si, Zr, Al, La etc.) | 30-60 | ~5 |
| BaTiO₃ | >200 | ~5 |

The field management layer 506 may either be grown using standard growth techniques (e.g. any suitable epitaxy technique including, but not limited to VPE, MBE, LPE, SPE) or deposited using standard deposition technologies (e.g. atomic layer deposition, sputtering, CVD, MOCVD, electron beam or thermal evaporation) at the end of device fabrication without altering the baseline fabrication flow.

FIG. 5(b) shows the electric field distribution within device 500 where the drain-to-source voltage (V_{DS}) is about 1000 Volts. As shown, with the electric field management layer 506 in place, the peak electric field is reduced at the junction 514 between the dielectric passivation layer, the gate terminal, and the electric field management layer 506. Although the examples above illustrate FinFET devices with high dielectric constant electric field management layers, other semiconductor devices can also utilize electric field management layers with high dielectric constants. Such devices include, but are not limited to MOSFETs, Schottky diodes, TMBSs, JBSs, PN diodes, MPSs, Trench MPSs, Fin diodes, multi-channel diodes, CAVETs, Trench CAVETs, Trench MOSFETs, HEMTs, MIS HEMTs, Fin channel HEMTs, Multi-channel HEMTs, Gate injector transistors, and the like.

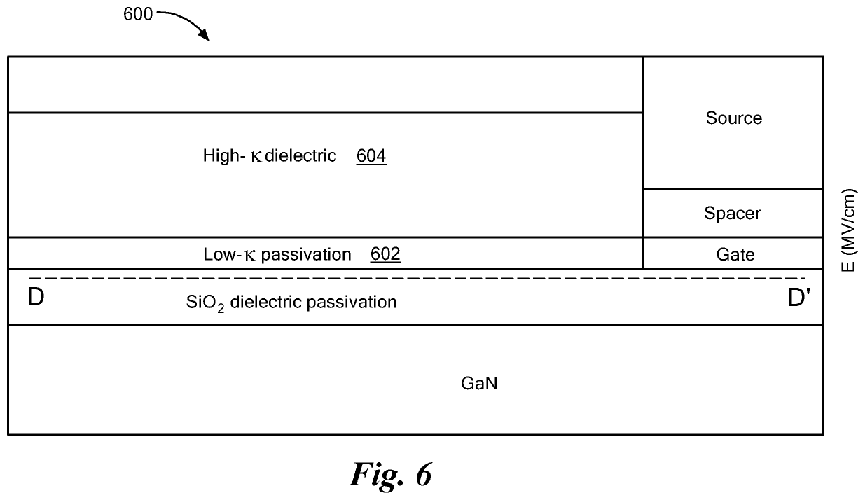

Referring to FIG. 6, surface passivation of the semiconductor surface can affect reliable operation of semiconductor devices. In some instances, high-κ dielectric layers directly deposited on top of the semiconductor surface may not provide the desired surface passivation due to non-idealities related to the interface between high-κ dielectric and underlying material. To mitigate this effect, a passivation layer 602 can be inserted between the high-κ dielectric layer 604 and underlying materials. In semiconductor device 600, for example, a low-κ passivation layer 602 has been inserted between high-κ dielectric layer 604 and underlying material.

In some instances, the permittivity of the high-κ electric field management layer 604 may be graded. For example, the top portion of layer 604 may have a higher permittivity κ than the bottom portion of layer 604. A graded layer 604 may be used in place of the low-κ passivation layer 602 to mitigate the effect of surface passivation. Alternatively, a graded electric field management layer 604 may be used in conjunction with a separate passivation layer 602.

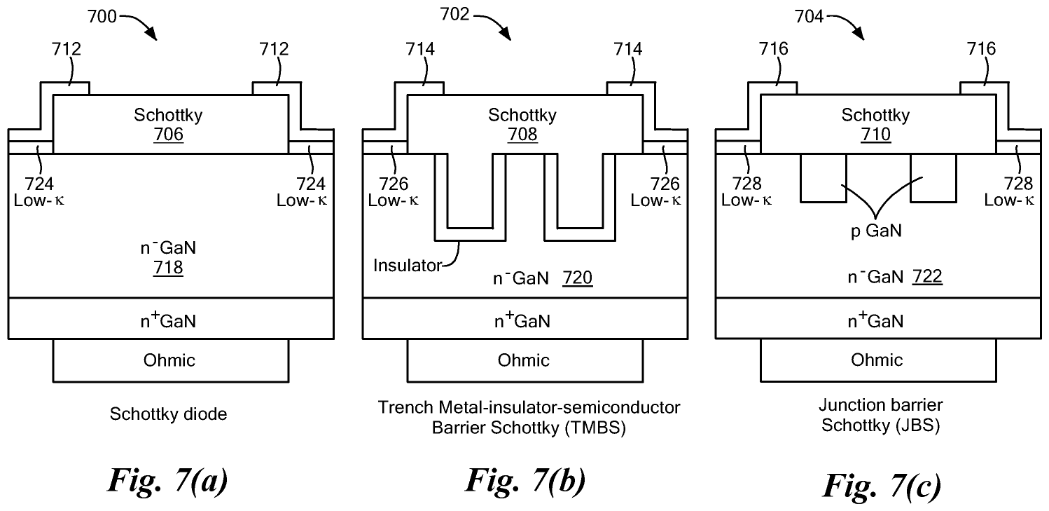

FIGS. 7(a), 7(b), and 7(c) are cross sectional images of vertical diodes 700, 702, 704 that include high-κ electric field management layers 712, 714, and 716, respectively. In this example, diode 700 is a traditional Schottky diode, diode 702 is a Trench Metal-insulator-semiconductor Barrier Schottky diode, and diode 704 is a Junction barrier Schottky diode. Each diode includes a Schottky barrier metal structure (e.g. structures 706, 708, 710) disposed on a respective negatively doped GaN layer (e.g. layers 718, 720, 722). A respective low-κ layer (e.g. layers 724, 726, 728) is positioned between the electric field management layers 712, 714, 710 and the GaN layers 718, 720, 722).

In certain instances, a peak electric field may form at the interface or corner between layers within the semiconductor device. For example, in FIG. 7(a), a peak electric field may form at position 750, where the interface between the Schottky metal structure and the low-κ passivation layer is formed and/or at the interface between the Schottky metal structure and the GaN layer 718. Thus, as shown, the electric field management layer may be positioned adjacent to an interface or corner of two other layers. For example, in FIG. 7(a), electric field management layer is placed adjacent to the interface between the Schottky metal structure and the low-κ passivation layer.

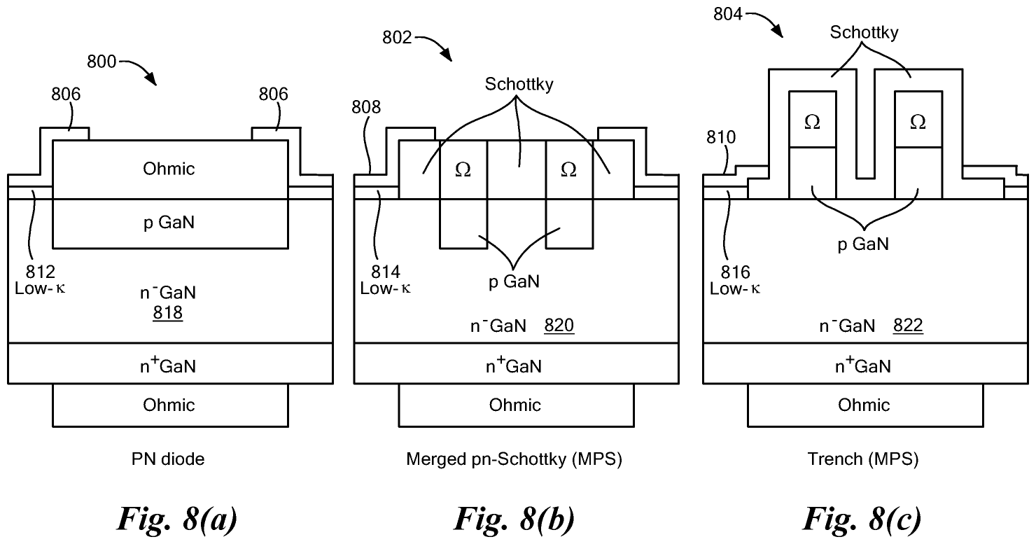

FIGS. 8(a), 8(b), and 8(c) are also cross sectional images of vertical diodes 800, 802, 804 that include high-κ electric field management layers 806, 808, 810, respectively. In this example, diode 800 is a PN junction diode, diode 802 is a Merged PN-Schottky diode, and diode 804 is a Trench MPS diode. In each diode, a respective low-κ layer (e.g. layers 812, 814, 816) is positioned between the relatively high-κ electric field management layers 806, 808, 810 and the GaN layers 818, 820, 822.

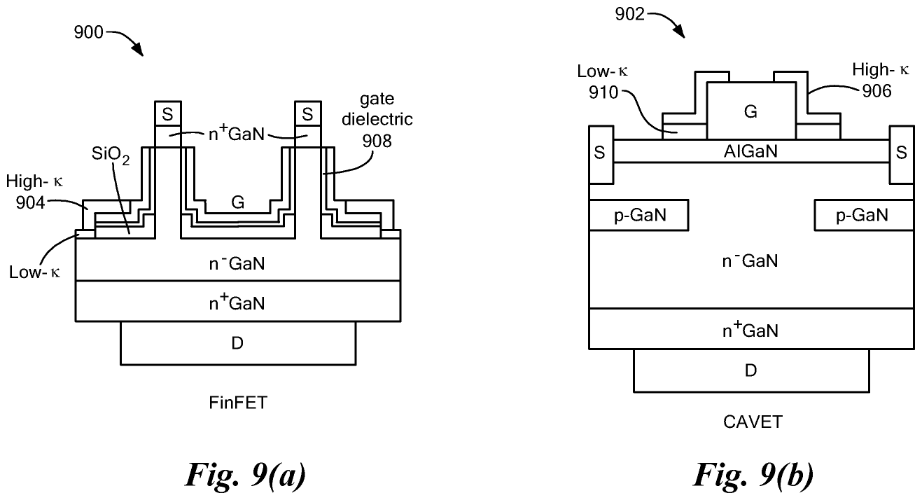

FIGS. 9(a) and 9(b) are cross sectional images of vertical transistors 900 and 902 that include high-κ electric field management layers 904 and 906, respectively. In these examples, a portion of each electric field management layer 904 and 906 is disposed on a gate region of the transistor (indicated by “G”), and a portion of each electric field management layer 904, 906 is disposed on a relatively low-κ layer. As described above, the electric field management layer 904 and 906 may reduce the peak value of an electric field which may occur at the corner and/or interface of the gate and the low-κ layer (e.g. at positions 908 and 910).

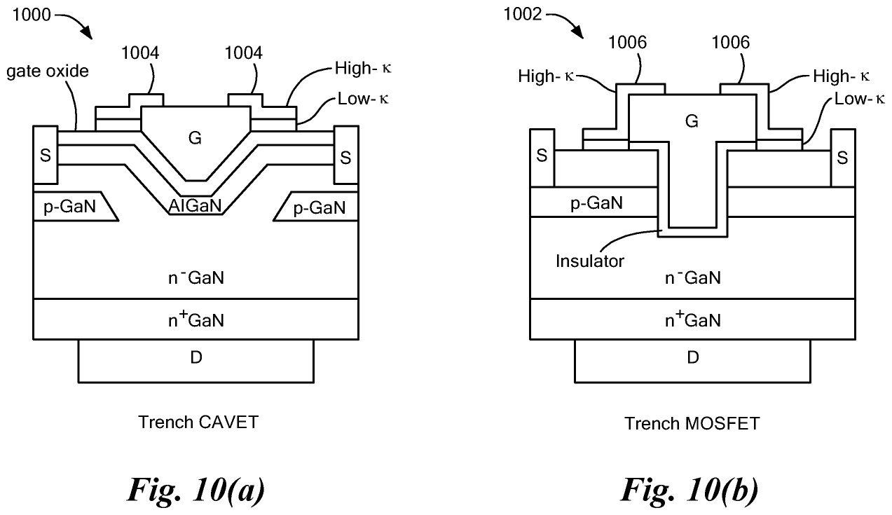

FIGS. 10(a) and 10(b) are also cross sectional images of vertical transistors 1000 and 1002 that include high-κ electric field management layers 1004 and 1006, respectively. Transistor 1000 is an example of a Trench CAVET transistor and transistor 1002 is an example of a Trench MOSFET. In these examples, a portion of each electric field management layer 1004 and 1006 is disposed on a gate region of the transistor (indicated by “G”), and a portion of each electric field management layer 1004, 1006 is disposed on a relatively low-κ layer (i.e. a layer that has a κ value less than that of the high-κ electric field management layer). As described above, the electric field management layer 1004 and 1006 may reduce the peak value of an electric field which may occur at the corner and/or interface of the gate and the low-κ layer.

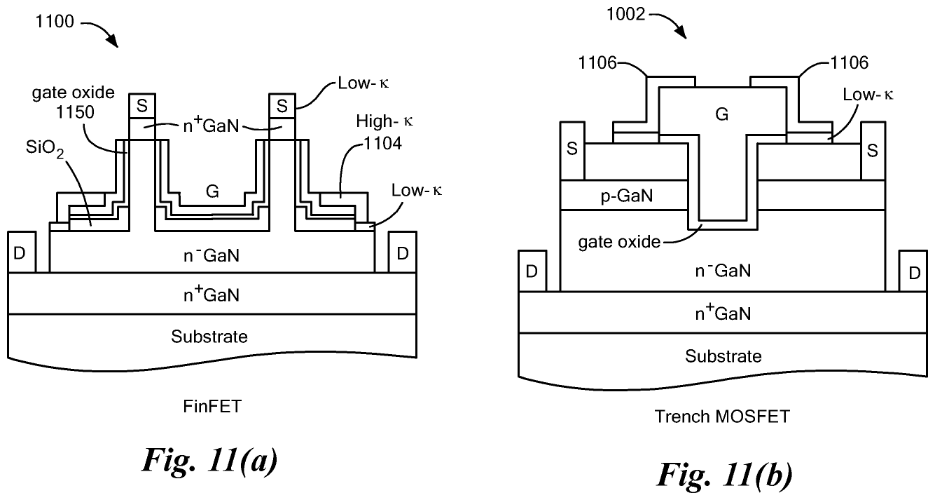

FIGS. 11(a) and 11(b) are cross sectional images of quasi-vertical transistors 1100 and 1102 that include high-κ electric field management layers 1104 and 1106, respectively. Transistor 1100 is an example of a FinFET transistor and transistor 1102 is an example of a Trench MOSFET. In these examples, a portion of each electric field management layer 1104 and 1106 is disposed on a gate region of the transistor (indicated by “G”), and a portion of each electric field management layer 1104, 1106 is disposed on a relatively low-κ layer (i.e. a layer that has a κ value less than that of the high-κ electric field management layer). As described above, the electric field management layer 1104 and 1106 may reduce the peak value of an electric field which may occur at the corner and/or interface of the gate and the low-κ layer.

In certain instances, a peak electric field may form at the interface or corner between multiple layers within the semiconductor device. For example, in FIG. 11(a), a peak electric field may form at or near position 1150, where there is an interface between multiple layers such as a two-way interface, a three-way interface, or an interface with an arbitrary number of layers. In this example, the interface contains multiple layers (e.g. the gate layer, the gate oxide layer, the SiO₂ layer, and a low-κ passivation layer. Thus, as shown, the electric field management layer may be positioned adjacent to the corner or interfaces between these multiple layers to mitigate a peak electric field that may occur at or near position 1150.

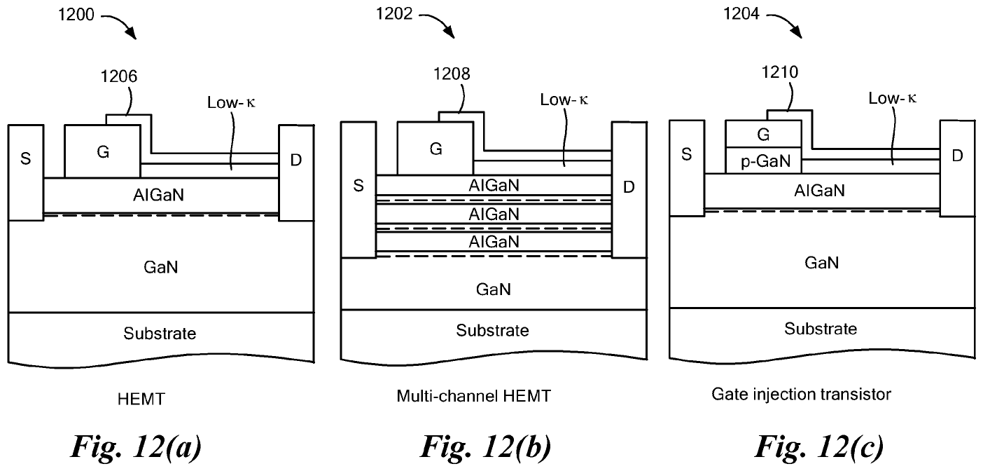

FIGS. 12(a), 12(b), and 12(c) are cross sectional images of lateral transistors 1200, 1202, and 1204 that include high-κ electric field management layers 1206, 1208, and 1210, respectively. Transistor 1200 is an example of a HEMT transistor, transistor 1202 is an example of a multi-channel HEMT transistor, and transistor 1104 is an example of a gate injection transistor. In these examples, a portion of each electric field management layer 1206, 1208, 1210 is disposed on a gate region of the transistor (indicated by “G”), and a portion of each electric field management layer 1206, 1208, 1210 is disposed on a relatively low-κ layer (i.e. a layer that has a κ value less than that of the high-κ electric field management layer). As described above, the electric field management layers 1206, 1208, 1210 may reduce the peak value of an electric field which may occur at the corner and/or interface of the gate and the low-κ layer.

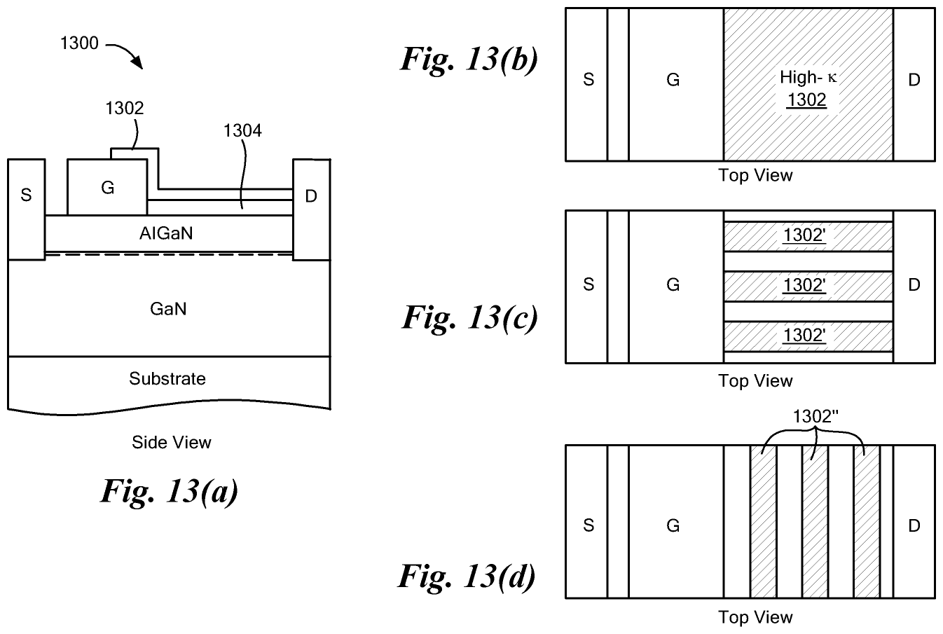

FIG. 13(a) is a cross sectional image of HEMT transistor 1300 having a high-κ electric field management layer 1302 disposed partially on a gate layer G and a low-κ layer 1304. FIGS. 13(b)-(d) are top views of the HEMT transistor 1300. The electric field management layer 1302 may be formed with varying geometric configurations, as shown by the top views of FIGS. 13(b)-(d). In FIG. 13(b), the electric field management layer 1302 may form a solid sheet that covers all or most of the low-κ layer. Alternatively, in FIG. 13(c), the electric field management layer 1302′ may comprise a series of strips extending from the gate G to the drain structure D. In another example, in FIG. 13(d), the electric field management layer 1302″ may comprise a series of strips positioned in parallel to the gate structure D and the drain structure D. In general, the electric field management layer may comprise multiple deposits of material (such as the strips shown in FIGS. 13(b)-(d)) arranged in a pattern. The deposits of material may be separated by voids or gaps in the electric field management layer (such as the gaps between the strips shown in FIGS. 13(b)-(d)). This configuration allows for a more accurate engineering of the electric field in the device.

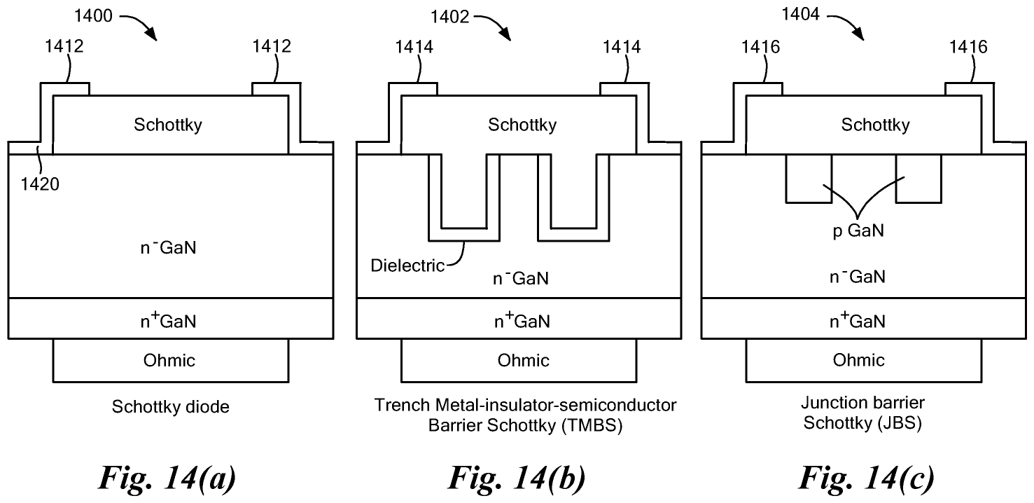

FIGS. 14(a), 14(b), and 14(c) are cross sectional images of vertical diodes 1400, 1402, 1404 that include high-κ electric field management layers 1412, 1414, and 1416, respectively. Diodes 1400, 1402, and 1404 are similar to diodes 700, 702, and 704 in FIGS. 7(a), 7(b), and 7(c). However, unlike diodes 700, 702, and 704, diodes 1400, 1402, and 1404 lack a relatively low-κ layer disposed between the electric field management layers 1412, 1414, and 1416 and the n-GaN layers. Thus, a portion of the electric field management layers 1412, 1414, and 1416 are disposed on a respective Schottky barrier metal structure, and a portion of the electric field management layers 1412, 1414, and 1416 are disposed directly on the GaN layers to reduce peak electric fields at the corners and/or interface of the Schottky barrier metal structure and the GaN layers (e.g. point 1420).

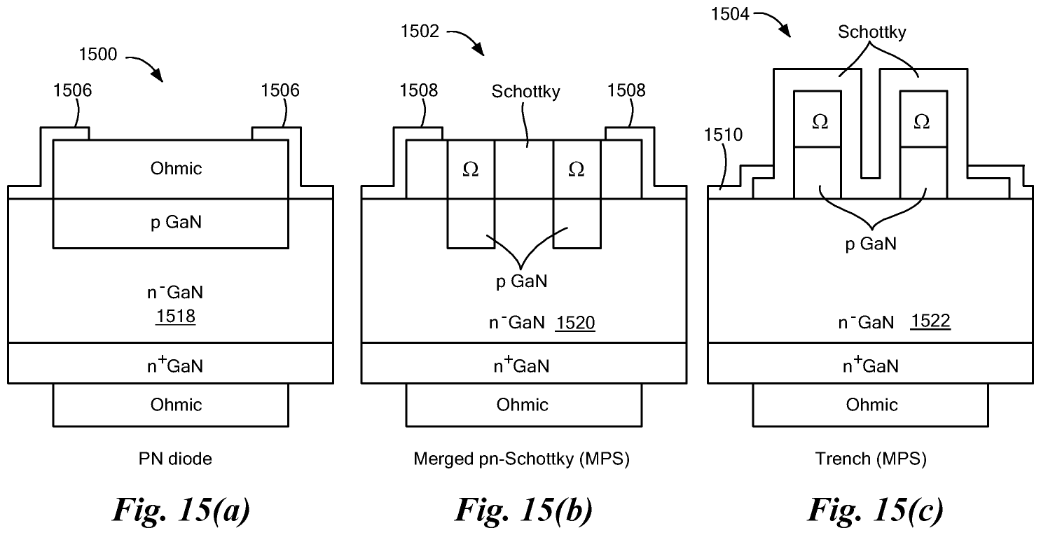

FIGS. 15(a), 15(b), and 15(c) are also cross sectional images of vertical diodes 1500, 1502, 1504 that include high-κ electric field management layers 1506, 1508, 1510, respectively. In this example, diode 1500 is a PN junction diode, diode 1502 is a Merged PN-Schottky diode, and diode 1504 is a Trench MPS diode. Diodes 1500, 1502, 1504 are similar to diodes 800, 802, 804 described above. However, unlike diodes 800, 802, 804, the diodes 1500, 1502, 1504 do not have respective low-κ layers positioned between the electric field management layers 1506, 1508, 1510 and the GaN layers 1518, 1520, 1522. Thus, a portion of electric field management layer 1506 is disposed on ohmic layer 1524 and another portion of electric field management layer 1506 is disposed directly on GaN layer 1518. Similarly, a portion of electric field management layer 1508 is disposed on a Schottky metal layer and a portion of electric field management layer 1508 is disposed directly on GaN layer 1520. Likewise, a portion of electric field management layer 1510 is disposed on a Schottky metal layer and a portion of electric field management layer 1510 is disposed directly on GaN layer 1522. In each instance, the high-κ electric field management layer is positioned to mitigate and reduce peak electric fields at the junction of the GaN layer and the other layers (e.g. the ohmic layers and/or Schottky metal layers) disposed on the GaN layers.

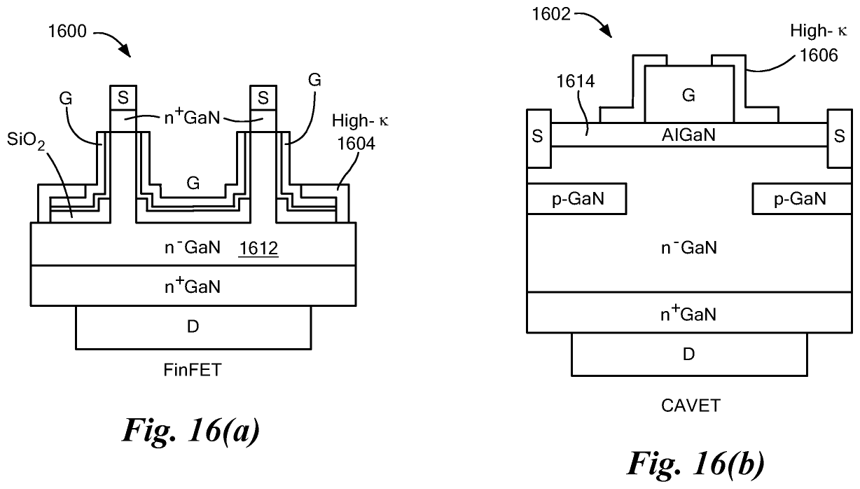

FIGS. 16(a) and 16(b) are cross sectional images of vertical transistors 1600 and 1602 that include high-κ electric field management layers 1604 and 1606, respectively. In these examples, a portion of each electric field management layer 1604 and 1606 is disposed on a gate region of the transistor (indicated by “G”). Also, a second portion of electric field management layer 1604 is disposed on n-GaN layer 1612 and a second portion of electric field management layer 1606 is disposed on AlGaN layer 1614. As described above, the electric field management layers 1604 and 1606 may reduce the peak value of an electric field which may occur at the corner and/or interface of the gate layer and the other layers (e.g. GaN layer 1612 or AlGaN layer 1614).

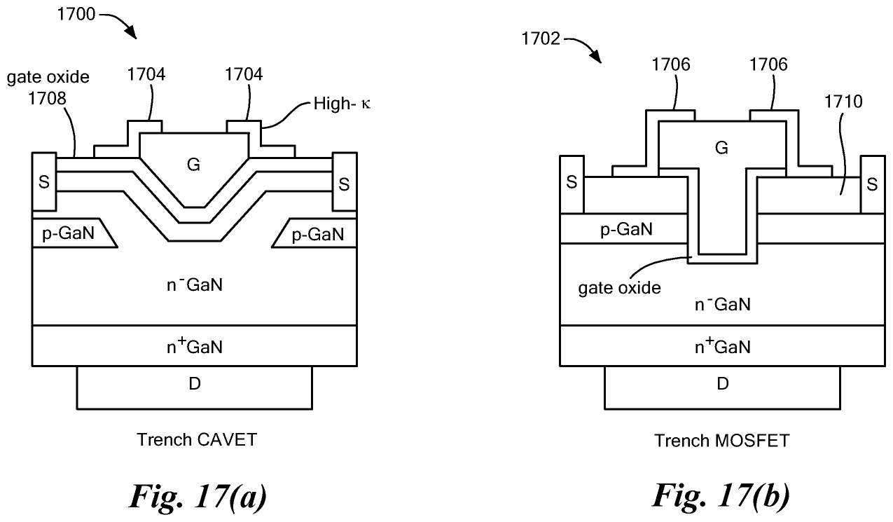

FIGS. 17(a) and 17(b) are also cross sectional images of vertical transistors 1700 and 1702 that include high-κ electric field management layers 1704 and 1706, respectively. Transistor 1700 is an example of a Trench CAVET transistor and transistor 1702 is an example of a Trench MOSFET. In these examples, a portion of each electric field management layer 1704 and 1706 is disposed on a gate region of the transistor (indicated by “G”). In transistor 1700, a portion of electric field management layer 1704 is disposed on a gate oxide layer 1708. In transistor 1702, a portion of electric field management layer 1706 is disposed on a GaN layer 1710. The electric field management layers 1704 and 1706 may reduce the peak value of an electric field which may occur at the corner and/or interface of the gate and other layers (e.g. the gate oxide layer 1708 or the GaN layer 1710) to reduce the possibility of a strong electric field causing breakdown of the transistor.

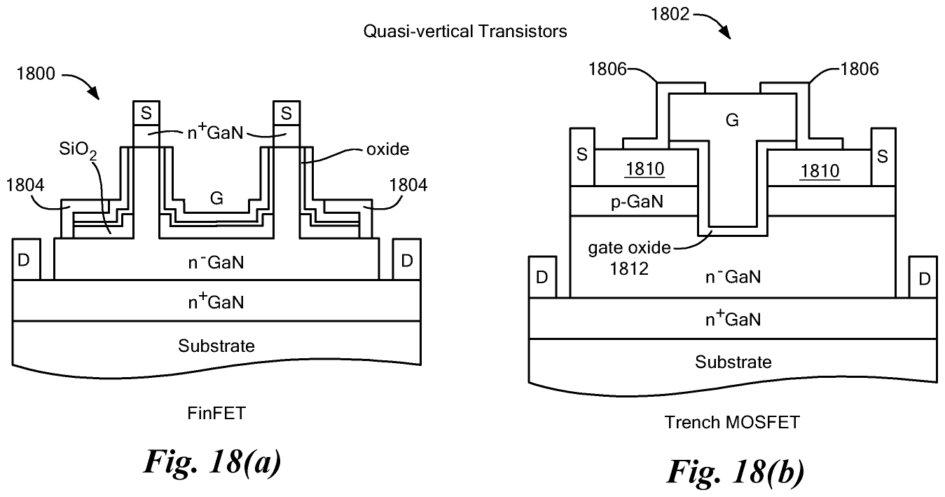

FIGS. 18(a) and 18(b) are cross sectional images of quasi-vertical transistors 1800 and 1802 that include high-κ electric field management layers 1804 and 1806, respectively. Transistor 1800 is an example of a FinFET transistor and transistor 1802 is an example of a Trench MOSFET. In these examples, a portion of each electric field management layer 1804 and 1806 is disposed on a gate region of the transistor (indicated by “G”). In transistor 1800, a portion of the electric field management layer 1804 is disposed on GaN layer 1808, and may make contact with the SiO₂ layer and/or the oxide layer between the gate layer and the GaN layer. In transistor 1802, a portion of the electric field management layer is disposed on GaN layer 1810 and may make contact with the gate oxide layer 1812 between GaN Layer 1810 and the gate layer G. As described above, the electric field management layers 1804 and 1806 may reduce the peak value of an electric field which may occur at the corner and/or interface of the gate and the other layers.

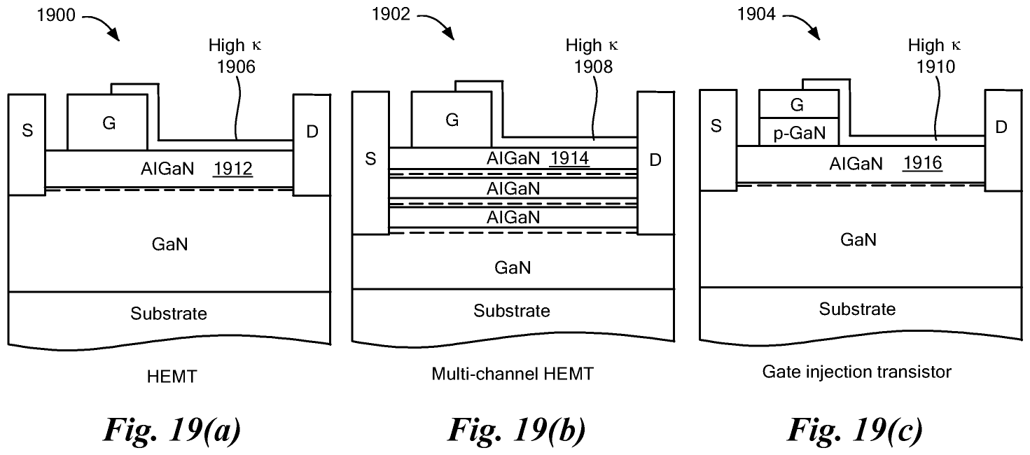

FIGS. 19(a), 19(b), and 19(c) are cross sectional images of lateral transistors 1900, 1902, and 1904 that include high-κ electric field management layers 1906, 1908, and 1910, respectively. Transistor 1900 is an example of a HEMT transistor, transistor 1902 is an example of a multi-channel HEMT transistor, and transistor 1904 is an example of a gate injection transistor. In these examples, a portion of each electric field management layer 1906, 1908, 1910 is disposed on a gate region of the transistor (indicated by “G”), and a portion of each electric field management layer 1906, 1908, 1910 is disposed on an AlGaN layer 1912, 1914, 1916, respectively. As described above, the electric field management layers 1906, 1908, 1910 may reduce the peak value of an electric field which may occur at the corner and/or interface of the gate and the low-κ layer.

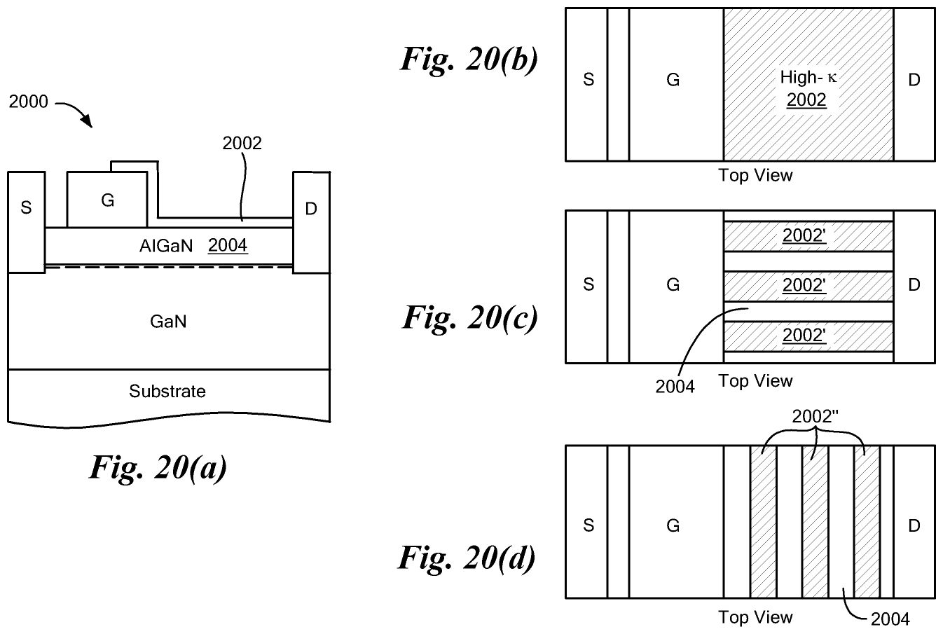

FIG. 20(a) is a cross sectional image of HEMT transistor 2000 having a high-κ electric field management layer 2002 disposed partially on a gate layer “G”. FIGS. 20(b)-(d) are top views of the HEMT transistor 2000. The electric field management layer 2002 may be formed with varying geometric configurations, as shown by the top views of FIGS. 20(b)-(d). In FIG. 20(b), the electric field management layer 2002 may form a solid sheet that covers all or most of the AlGaN layer. Alternatively, in FIG. 20(c), the electric field management layer 2002′ may comprise a series of strips extending from the gate G to the drain structure D. In another example, in FIG. 20(d), the electric field management layer 2002″ may comprise a series of strips positioned in parallel to the gate structure D and the drain structure D.

Various embodiments of the concepts, systems, devices, structures, and techniques sought to be protected are described above with reference to the related drawings. Alternative embodiments can be devised without departing from the scope of the concepts, systems, devices, structures, and techniques described. For example, illustrative embodiments described herein are provided having one field management structure. After reading the disclosure provided herein, however, it will be readily apparent that some embodiments may benefit from having more than one field management structure, and some of the field management structures could disposed in, on or around regions where the peak electric field is not the highest in the device. Thus, in summary, multiple field management structures provided in accordance with the concepts, structure and techniques described herein may be used for multiple electric field regions.

It is noted that various connections and positional relationships (e.g., over, below, adjacent, etc.) may be used to describe elements in the description and drawing. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

Also, the following definitions and abbreviations are to be used for the interpretation of the claims and the specification. The terms “comprise,” “comprises,” “comprising, “include,” “includes,” “including,” “has,” “having,” “contains” or “containing,” or any other variation are intended to cover a non-exclusive inclusion. For example, an apparatus, a method, a composition, a mixture or an article, that comprises a list of elements is not necessarily limited to only those elements but can include other elements not expressly listed or inherent to such apparatus, method, composition, mixture, or article.

Additionally, the term “exemplary” is means “serving as an example, instance, or illustration. Any embodiment or design described as “exemplary” is not necessarily to be construed as preferred or advantageous over other embodiments or designs. The terms “one or more” and “at least one” indicate any integer number greater than or equal to one, i.e. one, two, three, four, etc. The term “plurality” indicates any integer number greater than one. The term “connection” can include an indirect “connection” and a direct “connection”.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it may affect such feature, structure, or characteristic in other embodiments whether or not explicitly described.

Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top,” “disposed on,” “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

The disclosed subject matter is not limited in its application to the details of construction and to the arrangements of the components set forth in the following description or illustrated in the drawings. The disclosed subject matter is capable of other embodiments and of being practiced and carried out in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims.

1. A semiconductor device with electric field management, the semiconductor device comprising:
a substrate;
a dielectric passivation layer disposed on a drift region, the dielectric passivation layer having a dielectric constant;
a gate terminal disposed on the dielectric passivation layer; and
an electric field management layer having a dielectric constant which is higher than the dielectric constant of the dielectric passivation layer, the electric field management layer disposed over the dielectric passivation layer.

2. The semiconductor device of claim 1 the electric field management layer is disposed over the dielectric passivation layer so as to form a junction with the dielectric passivation layer at a location substantially proximate to a peak electric field within the semiconductor device.

3. The semiconductor device of claim 2 wherein the junction is formed at a three-way junction of the dielectric passivation layer, the electric field management layer, and the gate terminal.

4. The semiconductor device of claim 2 further comprising a gate dielectric layer disposed between the gate terminal and the dielectric passivation layer.

5. A semiconductor device comprising:
an electric field management layer formed from a first material;
wherein the electric field management layer is disposed over a first layer formed from a second, different material, with the first layer having a dielectric constant which is lower than the dielectric constant of the electric field management layer.

6. The semiconductor device of claim 5 wherein the first layer is provided as a dielectric passivation layer.

7. The semiconductor device of claim 5 further comprising a gate region, a source region and a drain region and wherein the electric field management layer is disposed adjacent to a gate terminal, wherein a dielectric passivation layer, electric field management layer, and gate terminal form a three-way junction.

8. A semiconductor structure comprising:
at least one semiconductor region that includes a semiconductor material;
two dielectric regions with arbitrary thickness, the two dielectric regions in contact with a wide bandgap semiconductor and with one of the dielectric regions having a relative permittivity which is higher than a relative permittivity of the other one of the dielectric regions; and
wherein the relative permittivity of at least one dielectric region is higher than the underlying semiconductor material.

9. The semiconductor structure of claim 8 wherein the semiconductor first material can be any of GaN, SiC, GaxO_{y}, diamond, silicon, GaAs, InₓAl₁₋ₓN, AlₓGa₁₋ₓN, c-BN, h-BN, MX₂ (where M=Mo, W; X=S, Se, Te).

10. The semiconductor structure of claim 8 wherein the dielectric regions and/or semiconductor material may be grown and/or deposited using any of a plurality of different techniques.

11. The semiconductor structure of claim 8 wherein the dielectric or semiconductor material may be grown using any of a plurality of techniques including, but not limited to metalorganic chemical vapor deposition or molecular-beam epitaxy.

12. The semiconductor structure of claim 8 wherein the dielectric or semiconductor material may be deposited using a plurality of techniques (e.g. atomic layer deposition, sputtering, chemical vapor deposition, spin-casting) or transferred.

13. The semiconductor structure of claim 8 wherein the dielectric material comprises one or more of: binary oxides (e.g., AlOₓ, HfOₓ, ZrOₓ, LaₓO_{y}, TiOₓ, NbOₓ, NiOₓ), nitrides (e.g. SiₓN_{y}, SiₓO_{y}N_{z}, SiₓO_{y}N_{z}H, AlNₓ, HfNₓ), doped oxides (HfₓM₁₋ₓO₂; M=Si, Zr, Al, La) semiconductors (e.g., AlN, Sc_{X}Al₁₋ₓN, Sc_{X}Ga₁₋ₓN, ScₓB₁₋ₓN), ferroelectrics (e.g., PZT, PVDF-TrFE, HfₓM₁₋ₓO where M=Al, Zr, Si, La etc.), complex oxides (e.g., BaTiO₃, SrTiO₃), or layered materials (e.g., GaSe, SnTe, h-BN, CuInP₂S₆) or their heterostructures with or without twisting in between layers (e.g., twisted bi-layer h-BN, MX₂ (where M=Mo, W, Hf, V, Nb; X=S, Se, Te)), or a graded composition of any of the materials above.

14. A semiconductor device comprising:
a first layer;
a second layer disposed on the first layer and forming an interface between the first layer and the second layer; and
an electric field management layer disposed on or near the interface, the electric field management layer having a higher dielectric constant than that of the first or second layer to reduce a peak electric field forming at the interface.

15. The semiconductor device of claim 14 wherein the first layer comprises a terminal of the semiconductor device.

16. The semiconductor device of claim 14 further comprising fourth layer disposed between the electric field management layer and the first layer, between the electric field management layer and the second layer, or both, the fourth layer comprising a material that has a lower permittivity than the permittivity of the electric field management layer.

17. The semiconductor device of claim 14 wherein the device is a transistor. Such devices include, but are not limited to MOSFETs, JFETs, multi-channel FETs, CAVETs, FinFETs, Trench CAVETs, Trench MOSFETs, HEMTs, MIS HEMTs, Fin channel HEMTs, Multi-channel HEMTs, Gate injector transistors, and the like.

18. The semiconductor device of claim 14 wherein the device is a diode. . Such devices include, but are not limited to Schottky diodes, TMBSs, JBSs, PN diodes, MPSs, Trench MPSs, Fin diodes, multi-channel diodes, and the like.

19. The semiconductor device of claim 14 wherein the electric field management layer comprises one or more of: binary oxides (e.g., AlOₓ, HfOₓ, ZrOₓ, LaxO_{y}, TiOₓ), nitrides (e.g. SiₓN_{y}, SiₓO_{y}N_{z}, SiₓO_{y}N_{z}H, AlNₓ, HfNₓ), doped oxides (HfₓM₁₋ₓO₂; M=Si, Zr, Al, La) semiconductors (e.g., AlN, Sc_{X}Al₁₋ₓN, Sc_{X}Ga₁₋ₓN, ScₓB₁₋ₓN), ferroelectrics (e.g., HZO, PZT, PVDF-TrFE), complex oxides including perovskites (e.g., BaTiO₃, SrTiO₃, LiNbO₃), or layered materials (e.g., GaSe, SnTe, h-BN, CuInP₂S₆) or their heterostructures with or without twisting in between layers (e.g., twisted bi-layer h-BN, twisted bi-layer MX₂ where M=Mo, W, Hf, V, Nb; X=S, Se, Te)), or a graded composition of any of the materials above.

20. The semiconductor device of claim 14 wherein the electric field management layer has a dielectric constant between about 9 and about 1000.

21. The semiconductor device of claim 14 wherein the electric field management layer comprises gaps.

22. The semiconductor device of claim 14 wherein a portion of the electric field management layer forms a spacer between the first and second layers.

23. The semiconductor device of claim 14 wherein the first and second layers comprise terminals of the semiconductor device.
